(19) United States
(12) Patent Application Publication
(10) Pub. No.: US 2023/0354604 A1
(43) Pub. Date: Nov. 2, 2023

(54) SEMICONDUCTOR DEVICE AND ELECTRONIC SYSTEM INCLUDING THE SAME

(71) Applicant: SAMSUNG ELECTRONICS CO., LTD., SUWON-SI (KR)

(72) Inventors: SEUNGMIN LEE, SUWON-SI (KR); JUNHYOUNG KIM, SUWON-SI (KR); YOUNGBUM WOO, SUWON-SI (KR); JOONSUNG LIM, SUWON-SI (KR)

(21) Appl. No.: 18/072,312

(22) Filed: Nov. 30, 2022

(30) Foreign Application Priority Data
Apr. 28, 2022 (KR) 10-2022-0052911

(51) Int. Cl. H10B 43/27; H10B 41/10; H01L 23/522; H01L 23/528; H10B 41/35; H10B 41/27; H10B 43/35; H10B 43/10

(52) U.S. Cl. CPC H01L 27/11582; H01L 27/11519; H01L 23/5226; H01L 23/5283; H01L 27/11524; H01L 27/11556; H01L 27/1157; H01L 27/11565

(57) ABSTRACT

A semiconductor device includes a first semiconductor structure including a first substrate, circuit devices disposed on the first substrate, and first metal bonding layers disposed on the circuit devices, and a second semiconductor structure including gate electrodes spaced apart from each other and stacked in a first direction, perpendicular to upper surfaces of the first metal bonding layers, channel structures passing through the gate electrodes, extending in the first direction, and respectively including a channel layer, second metal bonding layers disposed below the channel structures and the gate electrodes and connected to the first metal bonding layers, bit lines disposed below the channel structures, extending in a second direction, perpendicular to the first direction, and spaced apart from each other, and source lines disposed on the channel structures, extending in a third direction, perpendicular to the second direction, and spaced apart from each other. The channel structures are respectively disposed in intersection regions in which the bit lines and the source lines intersect each other.

### CROSS-REFERENCE TO RELATED APPLICATION(S)

This application claims the benefit under 35 U.S.C. § 119 of priority to Korean Patent Application No. 10-2022-0052911 filed on Apr. 28, 2022 in the Korean Intellectual Property Office, the disclosure of which is incorporated herein by reference in its entirety.

### BACKGROUND

One or more exemplary embodiments relate to a semiconductor device and an electronic system including the same.

In an electronic systems requiring data storage, a semiconductor device capable of storing high-capacity data is in high demand. Accordingly, a method of increasing the data storage capacity of a semiconductor device has been researched. For example, as a method of increasing data storage capacity of a semiconductor device, a semiconductor device including memory cells arranged three-dimensionally, instead of memory cells arranged two-dimensionally, has been proposed.

### SUMMARY OF THE INVENTION

An aspect of the present disclosure provides a semiconductor device with improved electrical properties and enhanced mass production characteristics.

Another aspect provides an electronic system that includes a semiconductor device with improved electrical properties and enhanced mass production characteristics.

According to an aspect, there is provided a semiconductor device that includes a first semiconductor structure including a first substrate, circuit devices disposed on the first substrate, and first metal bonding layers disposed on the circuit devices, and a second semiconductor structure including gate electrodes spaced apart from each other and stacked in a first direction, perpendicular to upper surfaces of the first metal bonding layers, channel structures passing through the gate electrodes, extending in the first direction, and respectively including a channel layer, second metal bonding layers disposed below the channel structures and the gate electrodes and connected to the first metal bonding layers, bit lines disposed below the channel structures, extending in a second direction, perpendicular to the first direction, and spaced apart from each other, and source lines disposed on the channel structures, extending in a third direction, perpendicular to the second direction, and spaced apart from each other. The channel structures may be respectively disposed in intersection regions in which the bit lines and the source lines intersect each other.

According to another aspect, there is provided a semiconductor device including a first substrate, circuit devices disposed on the first substrate, first metal bonding layers disposed on the circuit devices, gate electrodes spaced apart from each other and stacked in a first direction, perpendicular to upper surfaces of the first metal bonding layers, channel structures passing through the gate electrodes, extending in the first direction, and respectively including a channel layer, second metal bonding layers disposed below the channel structures and the gate electrodes and connected to the first metal bonding layers, bit lines electrically connected to the channel structures, extending in a second direction, perpendicular to the first direction, and spaced apart from each other, and source lines electrically connected to the channel structures, extending in a third direction, perpendicular to the second direction, and spaced apart from each other. A plurality of first selection channel structures may be selected from among the channel structures by an electrical signal applied to the channel layer through the bit lines, and a second selection channel structure may be selected from among the plurality of first selection channel structures by an electrical signal applied to the channel layer through the source lines.

According to another aspect, there is provided an electronic system including a semiconductor device including a first substrate, circuit devices disposed on the first substrate, first metal bonding layers disposed on the circuit devices, gate electrodes spaced apart from each other and stacked in a first direction, perpendicular to upper surfaces of the first metal bonding layers, channel structures passing through the gate electrodes, extending in the first direction, and respectively including a channel layer, second metal bonding layers disposed below the channel structures and the gate electrodes and connected to the first metal bonding layers, bit lines extending in a second direction, perpendicular to the first direction and spaced apart from each other, source lines extending in a third direction, perpendicular to the second direction and spaced apart from each other, and input/output pads electrically connected to the circuit devices, wherein a plurality of first selection channel structures are selected from among the channel structures by an electrical signal applied to the channel layer through the bit lines, and a second selection channel structure is selected from among the plurality of first selection channel structures by an electrical signal applied to the channel layer through the source lines, and a controller electrically connected to the semiconductor device through the input/output pad and controlling the semiconductor device.

In a structure in which two or more substrate structures are bonded to each other, structures of source lines and bit lines connected to a channel structure may be optimized, thereby providing a semiconductor device with improved electrical properties and enhanced mass production characteristics and an electronic system including the same.

The various beneficial advantages and effects of exemplary embodiments are not limited to the above description, and will be more easily understood in the course of describing specific exemplary embodiments.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic plan view of a semiconductor device according to exemplary embodiments;

FIG. 2 is a partially enlarged plan view of a semiconductor device according to exemplary embodiments;

FIG. 3 is a schematic cross-sectional view of a semiconductor device according to exemplary embodiments;

FIG. 4 is a schematic cross-sectional view of a semiconductor device according to exemplary embodiments;

FIG. 5 is a partially enlarged view of a semiconductor device according to exemplary embodiments;

FIG. 6 is a partially enlarged view of a semiconductor device according to exemplary embodiments;

FIG. 7 is a partially enlarged view of a semiconductor device according to exemplary embodiments;

FIG. 8 is a partially enlarged plan view of a semiconductor device according to exemplary embodiments;

FIG. 9 is a schematic circuit diagram of a semiconductor device according to exemplary embodiments;

FIG. 10 is a partially enlarged view of a semiconductor device according to exemplary embodiments;

FIG. 11 is a partially enlarged view of a semiconductor device according to exemplary embodiments;

FIG. 12 is a partially enlarged view of a semiconductor device according to exemplary embodiments;

FIG. 13 is a partially enlarged plan view of a semiconductor device according to exemplary embodiments;

FIG. 14 is a partially enlarged plan view of a semiconductor device according to exemplary embodiments;

FIGS. 15A to 15K are schematic cross-sectional views illustrating a method of manufacturing a semiconductor device according to exemplary embodiments;

FIG. 16 is a diagram schematically illustrating an electronic system including a semiconductor device according to exemplary embodiments;

FIG. 17 is a schematic perspective view of an electronic system including a semiconductor device according to an exemplary embodiment; and

FIG. 18 is a schematic cross-sectional view of a semiconductor package according to an exemplary embodiment.

### DETAILED DESCRIPTION OF THE PREFERRED EMBODIMENTS

Hereinafter, preferred exemplary embodiments will be described with reference to the accompanying drawings. Hereinafter, it can be understood that terms such as “upper,” “upper portion,” “upper surface,” “lower,” “lower portion,” “lower surface,” “side surface,” and the like are referred to with reference to the drawings, unless otherwise specified.

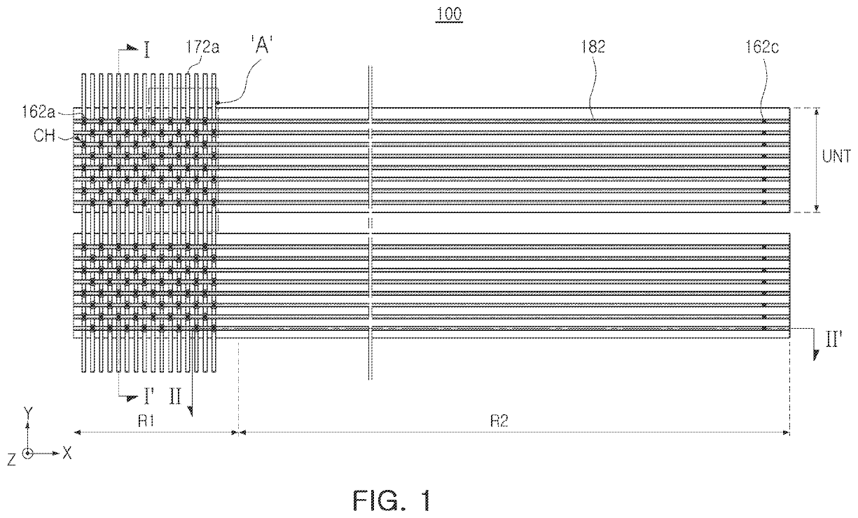

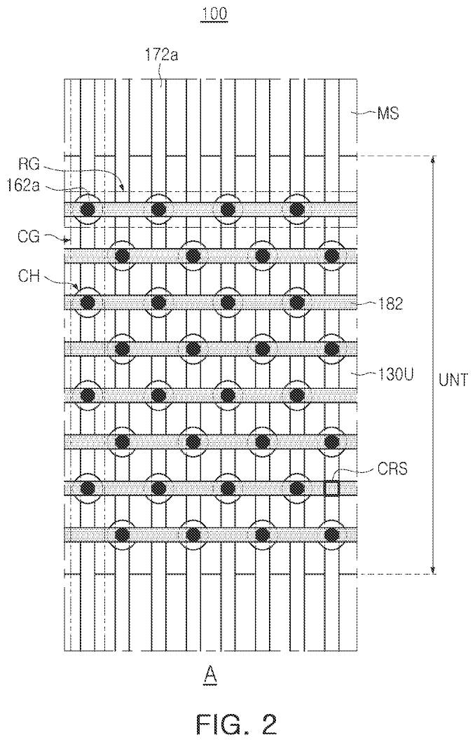

FIGS. 1 and 2 are a schematic plan view and a partially enlarged plan view of a semiconductor device according to exemplary embodiments.

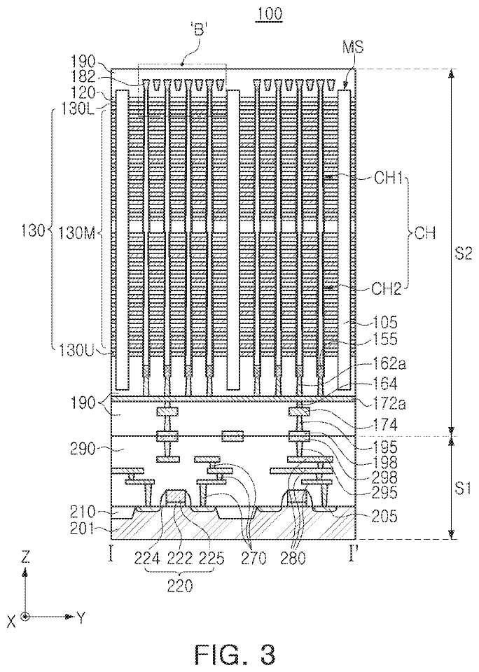

FIG. 3 is a schematic cross-sectional view of a semiconductor device according to exemplary embodiments. FIG. 3 illustrates a cross-section taken along line I-I′ in FIG. 1.

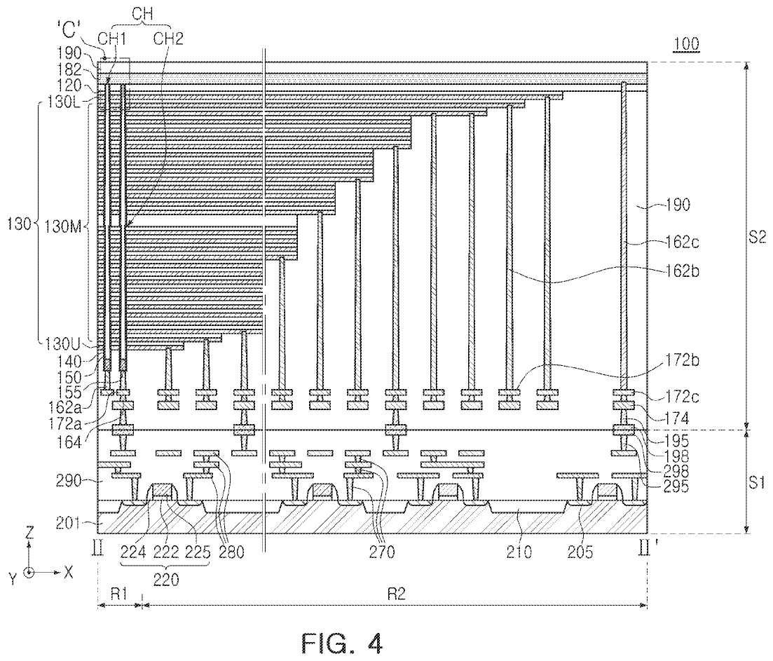

FIG. 4 is a schematic cross-sectional view of a semiconductor device according to exemplary embodiments. FIG. 4 illustrates a cross-section taken along line II-II′ in FIG. 1.

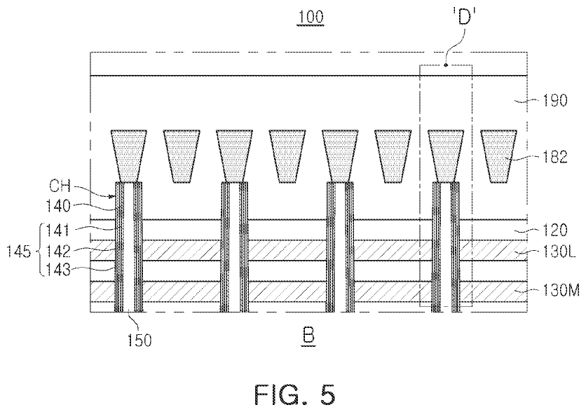

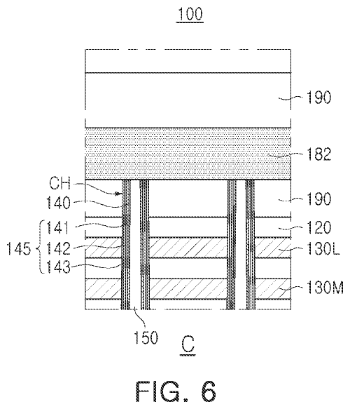

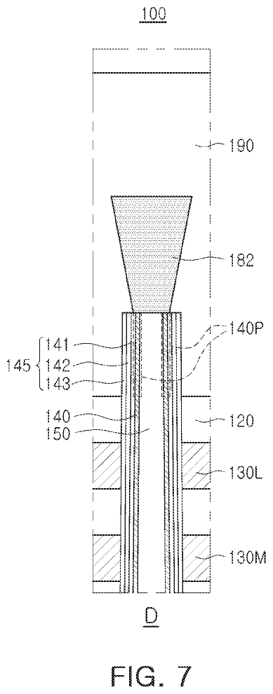

FIGS. 5 to 7 are partially enlarged views of semiconductor devices according to exemplary embodiments. FIG. 5 is an enlarged view of region “B” of FIG. 3, FIG. 6 is an enlarged view of region “C” of FIG. 4, and FIG. 7 is an enlarged view of region “D” of FIG. 5.

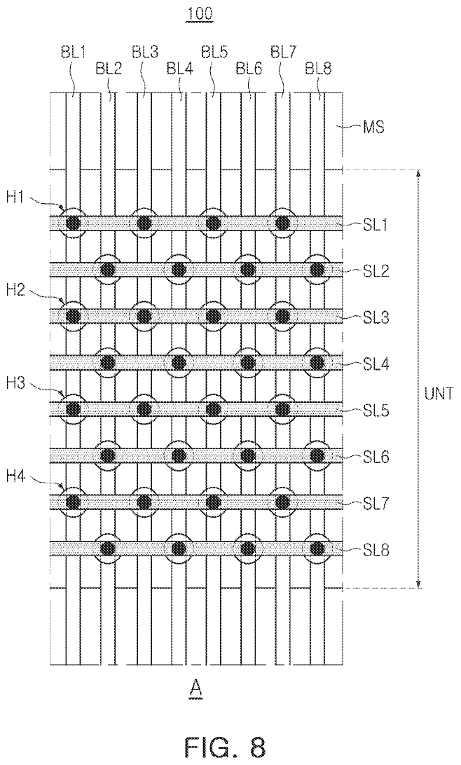

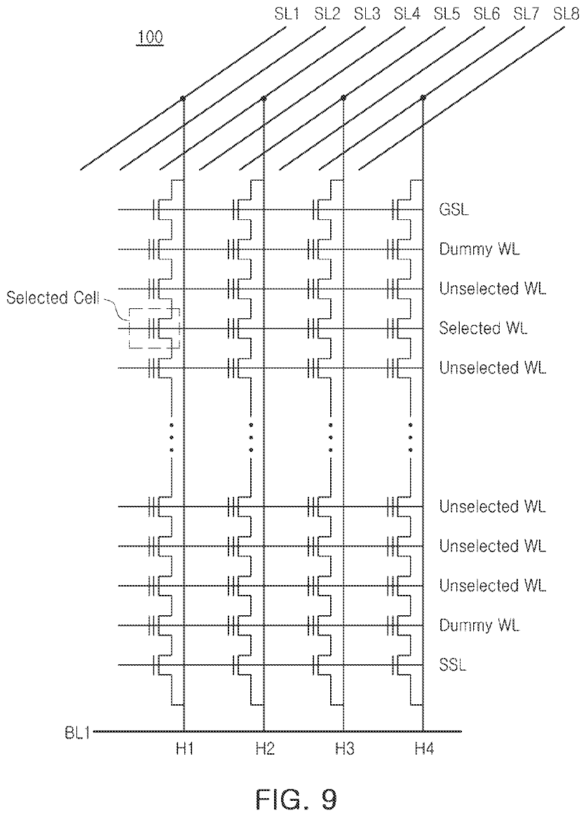

FIGS. 8 and 9 are a partially enlarged plan view and a schematic circuit diagram of a semiconductor device according to exemplary embodiments.

First, referring to FIGS. 1 to 7, a semiconductor device 100 may include first and second semiconductor structures S1 and S2 stacked vertically. For example, the first semiconductor structure S1 may include a peripheral circuit region of the semiconductor device 100, and the second semiconductor structure S2 may include a memory cell region of the semiconductor device 100. FIG. 1 illustrates an arrangement of the second semiconductor structure S2 in a plane with respect to channel structures CH, bit lines 172a, source lines 182, channel contact plugs 162a, and source contact plugs 162c.

The first semiconductor structure S1 may include a first substrate 201, source/drain regions 205 and device isolation layers 210 in the first substrate 201, circuit devices 220 disposed on the substrate 201, circuit contact plugs 270, circuit wiring lines 280, a peripheral region insulating layer 290, first bonding vias 295, and first metal bonding layers 298.

The first substrate 201 may have an upper surface extending in an X-direction and a Y-direction. The device isolation layers 210 may be formed on the first substrate 201 to define an active region. The source/drain regions 205 including impurities may be disposed in a portion of the active region. The first substrate 201 may include a semiconductor material, for example, a group IV semiconductor, a group III-V compound semiconductor, or a group II-VI compound semiconductor. For example, the first substrate 201 may be provided as a single crystal bulk wafer.

The circuit devices 220 may include planar transistors. Each of the circuit devices 220 may include a circuit gate dielectric layer 222, a spacer layer 224, and a circuit gate electrode 225. The source/drain regions 205 may be disposed in the first substrate 201 on both sides of the circuit gate electrode 225.

The peripheral region insulating layer 290 may be disposed on the circuit devices 220 on the first substrate 201. The circuit contact plugs 270 and the circuit wiring lines 280 may be included in a first wiring structure of the first semiconductor structure S1. The circuit contact plugs 270 may have a cylindrical shape, and may pass through the peripheral region insulating layer 290 to be connected to the source/drain regions 205. An electrical signal may be applied to the circuit devices 220 by the circuit contact plugs 270. In a region not illustrated, the circuit contact plugs 270 may also be connected to the circuit gate electrode 225. The circuit wiring lines 280 may be connected to the circuit contact plugs 270, may have a line shape, and may be disposed to have a plurality of layers. In exemplary embodiments, the number of layers of the circuit contact plugs 270 and the circuit wiring lines 280 may be changed in various manners.

The first bonding vias 295 and the first metal bonding layers 298 may be included in a first bonding structure, and may be disposed on portions of the uppermost circuit wiring lines 280. The first bonding vias 295 may have a cylindrical shape, and the first metal bonding layers 298 may have a circular pad shape or a relatively shorter line shape on a plane. Upper surfaces of the first metal bonding layers 298 may be exposed as an upper surface of the first semiconductor structure S1. The first bonding vias 295 and the first metal bonding layers 298 may function as bonding structures or bonding layers of the first semiconductor structure S1 and the second semiconductor structure S2. In addition, the first bonding vias 295 and the first metal bonding layers 298 may provide a path for an electrical connection with the second semiconductor structure S2. In exemplary embodiments, some of the first metal bonding layers 298 may be disposed only for bonding without being connected to the lower circuit wiring lines 280, as illustrated in FIG. 3. The first bonding vias 295 and the first metal bonding layers 298 may include a conductive material, for example, copper (Cu).

In exemplary embodiments, the peripheral region insulating layer 290 may include a bonding insulating layer having a predetermined thickness from an upper surface thereof. The bonding insulating layer may be a layer for dielectric-dielectric bonding with a bonding insulating layer of the second semiconductor structure S2. The bonding insulating layer may also function as a diffusion barrier layer of the first metal bonding layers 298, and may include, for example, at least one of SiO, SiN, SiCN, SiOC, SiON, and SiOCN.

The second semiconductor structure S2 may include gate electrodes 130, interlayer insulating layers 120 alternately stacked with the gate electrodes 130, channel structures CH disposed to pass through the gate electrodes 130, isolation regions MS passing through the gate electrodes 130 and extending in one direction, and a cell region insulating layer 190 covering the gate electrodes 130. The second semiconductor structure S2 may further include source lines 182 on the channel structures CH, and may omit a second substrate 101. The second semiconductor structure S2, a second wiring structure, may further include cell contact plugs 160 and cell wiring lines 170 disposed below the gate electrodes 130 and the channel structures CH. The second semiconductor structure S2, a second bonding structure, may further include second bonding vias 195 and second metal bonding layers 198.

The gate electrodes 130 may be spaced apart from each other and stacked in a Z-direction to form a stack structure together with the interlayer insulating layers 120. The stack structure may include vertically stacked lower and upper stack structures. However, in some exemplary embodiments, the stack structure may be formed of a single stack structure.

The gate electrodes 130 may include erase gate electrodes forming an erase transistor used for an erase operation, at least one lower gate electrode 130L forming a gate of a ground selection transistor, memory gate electrodes 130M forming a plurality of memory cells, and an upper gate electrode 130U forming gates of string selection transistors. Here, the lower gate electrode 130L and the upper gate electrode 130U may be referred to as “lower portion” and “upper portion” with respect to a direction used during a manufacturing process. The number of memory gate electrodes 130M forming the memory cells may be determined depending on a capacity of the semiconductor device 100. In some exemplary embodiments, the number of the upper and lower gate electrodes 130U and 130L and the erase gate electrodes may be 1 to 4 or more, respectively, and may have a structure that is the same as or different from the memory gate electrodes 130M. The erase gate electrodes may be disposed below the upper gate electrode 130U, and may be used for an erase operation using a gate induced drain leakage (GIDL) phenomenon. In exemplary embodiments, the erase gate electrodes may be further disposed on the lower gate electrode 130L. In addition, some of the gate electrodes 130, for example, the memory gate electrodes 130M adjacent to the upper or lower gate electrodes 130U and 130L may be dummy gate electrodes.

The gate electrodes 130 may be disposed so that at least some of them are isolated in predetermined units by the isolation regions MS in the Y-direction. Unit regions UNT of the gate electrodes 130 may be defined between a pair of adjacent isolation regions MS. One or more unit regions UNT may form one memory block.

In each of the unit regions UNT, an insulating region isolating the upper gate electrode 130U may be omitted. As the insulating region does not exist, dummy channel structures intersecting the insulating region may be omitted. As the dummy channel structures do not exist, a chip size reduction effect may be obtained. In the unit regions UNT, the upper gate electrode 130U may be in an equipotential state.

The interlayer insulating layers 120 may be disposed between the gate electrodes 130. In the same manner as the gate electrodes 130, the interlayer insulating layers 120 may be spaced apart from each other in the Z-direction, and may be disposed to extend in the X-direction and the Y-direction. The interlayer insulating layers 120 may include an insulating material such as silicon oxide or silicon nitride.

The cell region insulating layer 190 may be disposed to cover the source lines 182 and the gate electrodes 130 on lower surfaces of the source lines 182. The cell region insulating layer 190 may be formed of an insulating material, and may include a plurality of insulating layers.

The isolation regions MS may be disposed to pass through the gate electrodes 130 and extend in the X-direction. The isolation regions MS may be disposed to be parallel to each other. The isolation regions MS may pass through the entire stacked gate electrodes 130.

As illustrated in FIG. 3, an isolation insulating layer 105 may be disposed in the isolation regions MS. The isolation insulating layer 105 may have an inclined side surface so that a width thereof becomes narrower as a distance from the first semiconductor structure S1 increases due to a high aspect ratio. The isolation insulating layer 105 may include an insulating material, for example, silicon oxide, silicon nitride, or silicon oxynitride.

The channel structures CH may be disposed to be spaced apart from each other while forming rows and columns. The channel structures CH may be disposed to form a grid pattern or may be disposed to have a zigzag shape in one direction. The channel structures CH may have a columnar shape, and may have an inclined side surface so that a width thereof becomes narrower as a distance from the first semiconductor structure S1 increases according to an aspect ratio. Each of the channel structures CH may have a form in which first and second channel structures CH1 and CH2 respectively passing through the upper and lower stack structures of the gate electrodes 130 are connected to each other, and may have a bent portion caused by a difference or change in width in a connecting region.

A channel layer 140 may be disposed in the channel structure CH. In the channel structure CH, the channel layer 140 may be formed to have an annular shape surrounding an internal channel filling insulating layer 150. However, in some exemplary embodiments, the channel layer 140 may have a columnar shape such as a cylinder or prism without the channel filling insulating layer 150. An upper end of the channel layer 140 may be positioned on a level substantially the same as that of an upper end of a channel dielectric layer 145, but the present disclosure is not limited thereto. An upper surface of the channel layer 140 may be in direct contact with a lower surface of a source line 182. As illustrated in FIG. 7, the channel layer 140 may include a contact doping region 140P for ohmic contact with the source line 182. The channel layer 140 may further include impurities caused by doping, for example, N-type impurities in the contact doping region 140P. The depth of the contact doping region 140P may be changed in various manners. For example, a lower surface of the contact doping region 140P may be positioned on a level higher than that of an upper surface of the lower gate electrode 130L so that there is no overlapping region between the contact doped region 140P and the lower gate electrode 130L. The channel layer 140 may include a semiconductor material such as polycrystalline silicon or single crystal silicon. The channel layer 140 may further include impurities caused by doping, for example, N-type impurities in a region parallel to the erase gate electrodes.

The channel dielectric layer 145 may be disposed between the gate electrodes 130 and the channel layer 140. The channel dielectric layer 145 may extend vertically along the channel layer 140. A portion of the channel dielectric layer 145 may be exposed so as to be in contact with the cell region insulating layer 190. The channel dielectric layer 145 may include a tunneling layer 141, a charge storage layer 142, and a blocking layer 143 sequentially stacked from the channel layer 140. The tunneling layer 141 may tunnel a charge into the charge storage layer 142, and may include, for example, silicon oxide (SiO₂), silicon nitride (Si₃N₄), silicon oxynitride (SiON), or any combination thereof. The charge storage layer 142 may be a charge trapping layer or a floating gate conductive layer. The blocking layer 143 may include silicon oxide (SiO₂), silicon nitride (Si₃N₄), silicon oxynitride (SiON), a high-k dielectric material, or any combination thereof.

Channel pads 155 may be disposed only at a lower end of the lower second channel structure CH2. The channel pads 155 may include, for example, a doped semiconductor layer. For example, the channel pads 155 may be formed of polycrystalline silicon including first conductivity type impurities, for example, N-type impurities.

The channel layer 140, the gate dielectric layer 145, and the channel filling insulating layer 150 may be connected to each other between the first channel structure CH1 and the second channel structure CH2. A relatively thicker interlayer insulating layer 120 may be further disposed between the first channel structure CH1 and the second channel structure CH2. However, the shape of the interlayer insulating layers 120 may be changed in various manners in exemplary embodiments.

The source lines 182 may have a line shape extending in the X-direction, may be spaced apart from each other in the Y-direction, and may be disposed on the channel structures CH. The source lines 182 may extend through central axes in the X-direction of the channel structures CH. The source lines 182 may be disposed on the channel structures CH. In a case in which the source lines 182 are disposed on the channel structures CH, it may be relatively easy to perform a process of isolating the source lines 182 from each other, as compared to a case in which the source lines 182 are disposed below the channel structures CH. In the present exemplary embodiment, the source lines 182 may be disposed on the channel structures CH, respectively. The source lines 182 may be directly connected to the channel layer 140, and a lower surface of the source line 182 may be in direct contact with an upper surface of the channel layer 140. Each of the source lines 182 may be connected to the source contact plugs 162c, and may receive an electrical signal through the source contact plugs 162c to transmit the electrical signal to the channel layer 140. The source lines 182 may have an upper width greater than a lower width, and may have an inclined side surface so that a width thereof becomes narrower as a distance from the channel structures CH decreases. The source lines 182 may include a metal material, for example, aluminum (Al), copper (Cu), tungsten (W), titanium (Ti), tungsten nitride (WN), tantalum nitride (TaN), titanium nitride (TiN), or any combination thereof. The source lines 182 formed of a metal material may have a relatively lower resistance value than that of the source lines 182 formed of a semiconductor material.

The bit lines 172a may have a line shape extending in the Y-direction, may be spaced apart from each other in the X-direction, and may be disposed below the channel structures CH. The bit lines 172a may extend through central axes in the Y-direction of the channel structures CH. The bit lines 172a may be disposed below columns in the Y-direction of the channel structures CH, respectively. In the case in which the bit lines 172a are respectively disposed below the columns in the Y-direction of the channel structures CH, the bit lines 172a may have a relatively wider width, and the bit lines 172a may be formed without using a double patterning technology (DPT), as compared to a case in which two of the bit lines 172a are respectively disposed below the columns in the Y-direction of the channel structures CH. In the case in which the bit lines 172a are respectively disposed below the columns in the Y-direction of the channel structures CH, the number of page buffer circuits connected to the bit lines 172a may be reduced, and a chip size reduction effect may be obtained as the number of page buffer circuits is reduced, as compared to the case in which two of the bit lines 172a are respectively disposed below the columns in the Y-direction of the channel structures CH. The bit lines 172a may be electrically connected to the channel pads 155 and the channel layer 140 through the channel contact plugs 162a. The bit lines 172a may receive an electrical signal through a second cell contact plugs 164 to transmit the electrical signal to the channel layer 140. The bit lines 162a may have an inclined side surface so that a width thereof becomes narrower as a distance from the channel structures CH decreases. The bit lines 162a may include a metal material, for example, aluminum (Al), copper (Cu), tungsten (W), titanium (Ti), tungsten nitride (WN), tantalum nitride (TaN), titanium nitride (TiN), or any combination thereof.

As illustrated in FIG. 2, regions in which the source lines 182 and the bit lines 162a intersect each other may form intersection regions CRS. The number of intersection regions CRS may be obtained by multiplying the number of source lines 182 by the number of bit lines 162a. The channel structures CH may be disposed in the intersection regions CRS, respectively. Among the intersection regions CRS, intersection regions CRS in which the channel structures CH are not disposed may exist.

A plurality of channel structures CH may be selected from among the channel structures CH by an electrical signal applied to the channel layer 140 through the bit lines 162a, and one channel structure CH may be selected from among the plurality of channel structures CH by an electrical signal applied to the channel layer 140 through the source lines 182.

Among the channel structures CH, the channel structures CH arranged in a line with respect to the X-direction may form row groups RG, respectively. Each of the source lines 182 may be connected to only one row group RG among the row groups RG of the channel structures CH. Among the channel structures CH, the channel structures CH arranged in a line with respect to the Y-direction may form column groups CG, respectively. Each of the bit lines 162a may be connected to only one column group CG among the column groups CG of the channel structures CH.

The second wiring structure may include cell contact plugs 160 and cell wiring lines 170, and may be configured such that the second semiconductor structure S2 is electrically connected to the first semiconductor structure S1.

The cell contact plugs 160 may include first and second cell contact plugs 162 and 164, and the cell wiring lines 170 may include first and second cell wiring lines 172 and 174. The first cell contact plugs 162 may include channel contact plugs 162a, gate contact plugs 162b, and source contact plugs 162c. The channel contact plugs 162a may have an upper end connected to the channel pads 155, and may have a lower end electrically connected to the circuit devices 220 through the bit lines 172a. The gate contact plugs 162b may have an upper end connected to the gate electrodes 130, and may have a lower end electrically connected to the circuit devices 220 through a gate wiring line 172b. The source contact plugs 162c may have an upper end connected to the source lines 182, and may have a lower end electrically connected to the circuit devices 220 through a source wiring line 172c. The second cell contact plugs 164 may vertically connect the first and second cell wiring lines 172 and 174 to each other.

The cell contact plugs 160 may have a cylindrical shape. The cell contact plugs 160 may have different lengths. For example, the first cell contact plugs 162 may have a relatively longer length. The cell contact plugs 160 may have an inclined side surface so that a width thereof becomes narrower as a distance from the first semiconductor structure S1 increases, according to an aspect ratio.

The cell wiring lines 170 may have a linear shape extending in at least one direction. The first cell wiring lines 172 may include the bit lines 172a, the gate wiring lines 172b, and the source wiring lines 172c.

The second cell wiring lines 174 may be wiring lines disposed below the first cell wiring lines 172. The cell wiring lines 170 may have an inclined side surface so that a width thereof becomes narrower as a distance from the first semiconductor structure S1 increases.

The cell contact plugs 160 and the cell wiring lines 170 may include a metal material, for example, tungsten (W), aluminum (Al), copper (Cu), tungsten nitride (WN), tantalum nitride (TaN), titanium nitride (TiN), or any combination thereof.

The second bonding vias 195 of the second bonding structure may be disposed below the second cell wiring lines 174 to be connected to the second cell wiring lines 174, and the second metal bonding layers 198 of the second bonding structure may be connected to the second bonding vias 195. The second metal bonding layers 198 may have a lower surface exposed to a lower surface of the second semiconductor structure S2. The second metal bonding layers 198 may be bonded to and connected to the first metal bonding layers 298 of the first semiconductor structure S1. The second bonding vias 195 and the second metal bonding layers 198 may include a conductive material, for example, copper (Cu).

In exemplary embodiments, the cell region insulating layer 190 may include a bonding insulating layer having a predetermined thickness from a lower surface thereof. In this case, the bonding insulating layer may form dielectric-dielectric bonding with the bonding insulating layer of the first semiconductor structure S1. The bonding insulating layer may include, for example, at least one of SiO, SiN, SiCN, SiOC, SiON, and SiOCN.

The first and second semiconductor structures S1 and S2 may be bonded to each other by bonding between the first metal bonding layers 298 and the second metal bonding layers 198 and bonding between the bonding insulating layers. Bonding between the first metal bonding layers 298 and the second metal bonding layers 198 may be, for example, copper (Cu)-copper (Cu) bonding, and bonding between the bonding insulating layers may be, for example, dielectric-dielectric bonding such as SiCN-SiCN bonding. The first and second semiconductor structures S1 and S2 may be bonded to each other by hybrid bonding including copper (Cu)-copper (Cu) bonding and dielectric-dielectric bonding.

Referring to FIGS. 8 and 9, the bit lines 162a may include first to eighth bit lines BL1 to BL8. The source lines 182 may include first to eighth source lines SL1 to SL8. The channel structures CH may include first to fourth strings H1 to H4. The first to fourth strings H1 to H4 may be selected from among the channel structures CH by an electrical signal applied to a first bit line BL1, and a first string H1 may be selected from among the first to fourth strings H1 to H4 by an electrical signal applied to a first source line SL1. In such a case, the second to fourth strings H2 to H4 may be maintained in a program inhibit state by electrical signals applied to third, fifth, and seventh source lines.

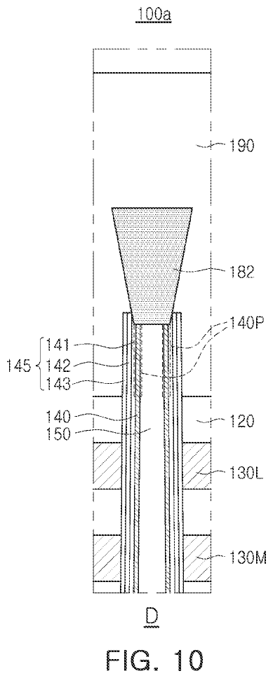

FIG. 10 is a partially enlarged view of a semiconductor device according to exemplary embodiments. FIG. 10 is an enlarged view of a region corresponding to region “D” of FIG. 5.

Referring to FIG. 10, in a semiconductor device 100a, a lower portion of the source line 182 may recess an upper portion of the channel structure CH, unlike that in the previous exemplary embodiment. A lower surface of the source line 182 may be in contact with the channel layer 140 in the channel structure CH. A portion of a side surface of the source line 182 may be in contact with the channel dielectric layer 145. In some exemplary embodiments, a depth at which the source line 182 recesses the channel structure CH may be changed in various manners in a range in which the lower surface of the source line 182 is positioned on a level higher than that of the lower gate electrode 130L.

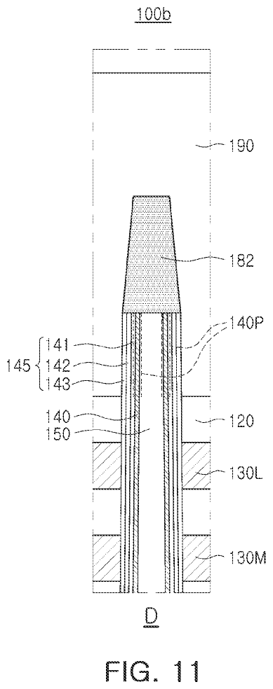

FIG. 11 is a partially enlarged view of a semiconductor device according to exemplary embodiments. FIG. 11 is an enlarged view of a region corresponding to region “D” of FIG. 5.

Referring to FIG. 11, in a semiconductor device 100b, the source lines 182 may have a lower width greater than an upper width, and may have an inclined side surface so that a width thereof becomes narrower as a distance from the channel structures CH increases, unlike that in the previous exemplary embodiment. During the manufacturing process of the semiconductor device 100b, for example, a metal material forming the source line 182 may be deposited, the metal material may be etched, and a region in which the metal material is etched may be filled with an insulating material, and thus the source line 182 may have the form described above.

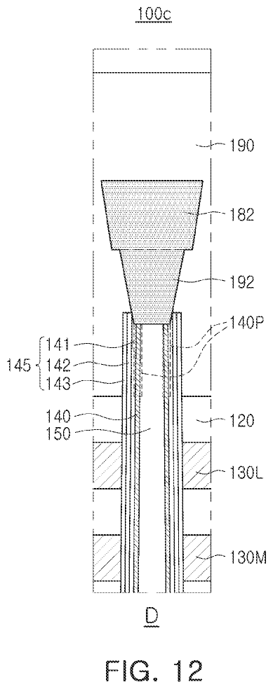

FIG. 12 is a partially enlarged view of a semiconductor device according to exemplary embodiments. FIG. 12 is an enlarged view of a region corresponding to region “D” of FIG. 5.

Referring to FIG. 12, a semiconductor device 100c may further include a via contact plug 192 connecting the source line 182 and the channel layer 140 to each other, unlike that in the previous exemplary embodiment. The via contact plug 192 may have a diameter less than that of the source line 182 in a region connected to the source line 182. A lower portion of the via contact plug 192 may have a recess in an upper portion of the channel structure CH. A lower surface of the via contact plug 192 may be in contact with the channel layer 140 in the channel structure CH. A portion of a side surface of the via contact plug 192 may be in contact with the channel dielectric layer 145. In exemplary embodiments, a depth at which the via contact plug 192 recesses the channel structure CH may be changed in various manners in a range in which the lower surface of the via contact plug 192 is positioned at a level higher than that of the lower gate electrode 130L.

The via contact plug 192 may be formed together with the source line 182 by, for example, a dual damascene process. In this case, the via contact plug 192 and the source line 182 may not be distinguishable from each other. In addition, when the source line 182 includes a barrier layer, the barrier layer may extend from a side surface of the source line 182 along the side surface and the lower surface of the via contact plug 192.

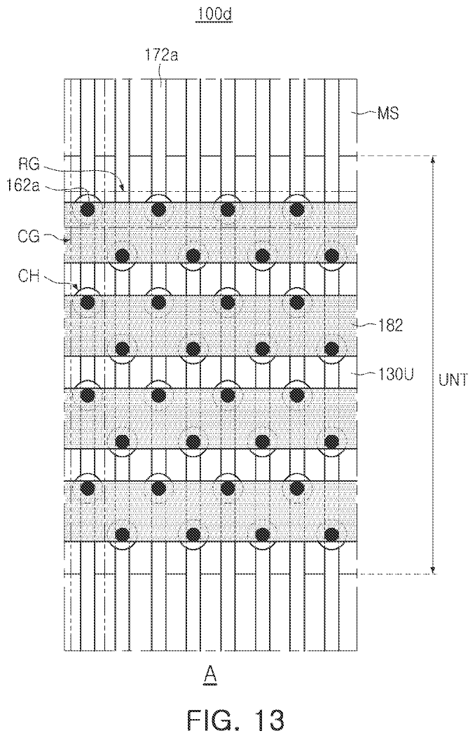

FIG. 13 is a partially enlarged plan view of a semiconductor device according to exemplary embodiments. FIG. 13 is an enlarged view of a region corresponding to region “A” of FIG. 1.

Referring to FIG. 13, in a semiconductor device 100d, each of the source lines 182 may be connected to two row groups RG among the row groups RG of the channel structures CH, unlike that in the previous exemplary embodiment. However, even in this case, the channel structures CH connected to one source line 182 may be connected to different bit lines 172a. In a case in which the source lines 182 are connected to the two row groups RG among the row groups RG of the channel structures CH, the number of source lines 182 may be reduced by half, as compared to a case in which the source lines 182 are connected to one row group RG among the row groups RG of the channel structures CH. As the number of source lines 182 is reduced, the number of source contact plugs 162c connected to the source lines 182 and the number of circuit devices 220 connected to the source contact plugs 162c may also be reduced. As the number of circuit devices 220 is reduced, a chip size may also be reduced.

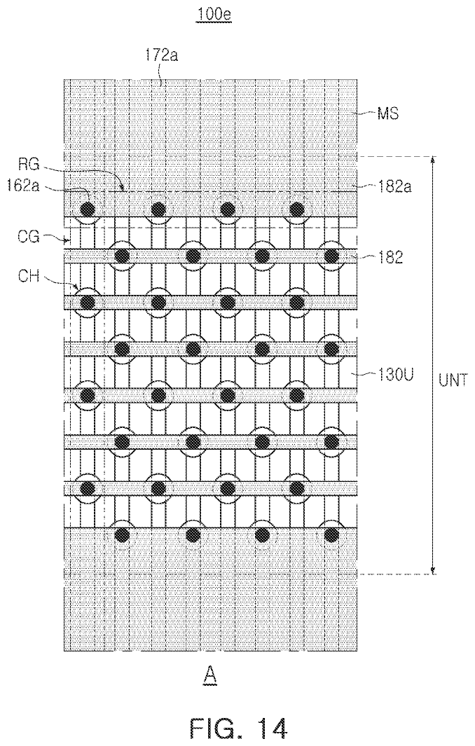

FIG. 14 is a partially enlarged plan view of a semiconductor device according to exemplary embodiments. FIG. 14 is an enlarged view of a region corresponding to region “A” of FIG. 1.

Referring to FIG. 14, in a semiconductor device 100e, the source lines 182 may further include block shared source lines 182a overlapping the isolation regions MS and extending in a Y-direction, unlike that in the previous exemplary embodiment. The block shared source lines 182a may be connected to two row groups RG among the row groups RG of the channel structures CH. The block shared source lines 182a may be connected to the channel structures CH disposed in two unit regions UNT. The block shared source lines 182a may be connected together to the channel structures CH adjacent to the isolation regions MS in the Y-direction in the two unit regions UNT adjacent to each other. In such a case in which the block shared source lines 182a exist, the number of source lines 182 may be reduced, as compared to a case in which the source lines 182 are connected to one row group RG among the row groups RG of the channel structures CH. As the number of source lines 182 is reduced, the number of source contact plugs 162c connected to the source lines 182 and the number of circuit devices 220 connected to the source contact plugs 162c may also be reduced. As the number of circuit devices 220 is reduced, a chip size may also be reduced.

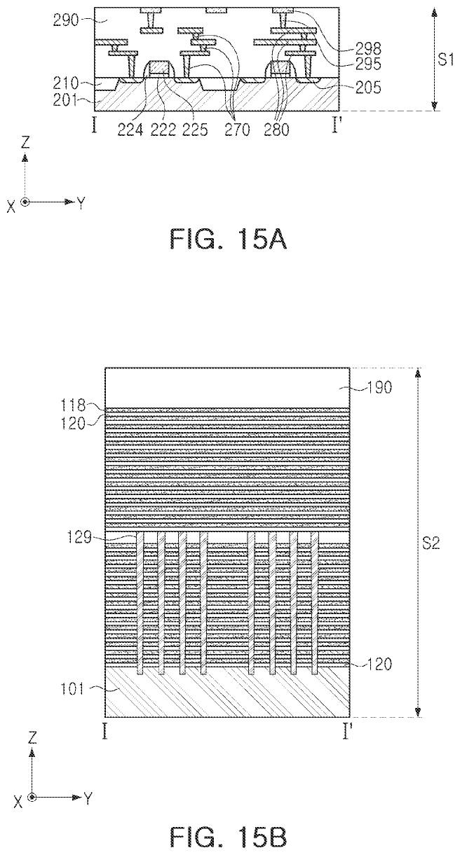

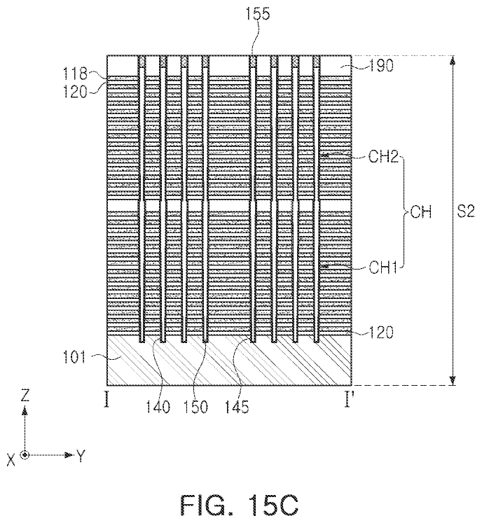

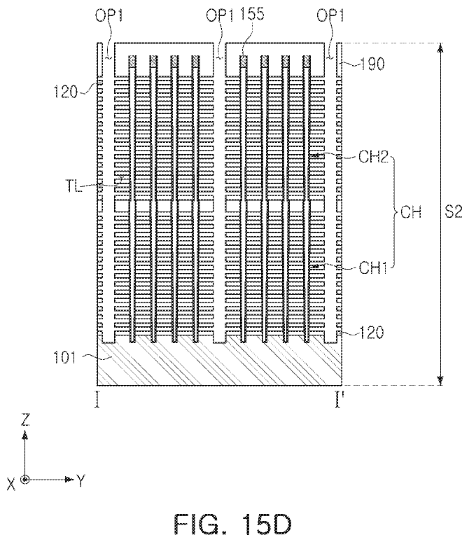

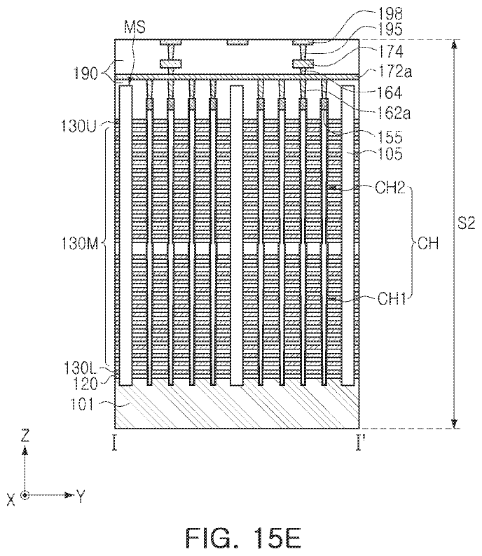

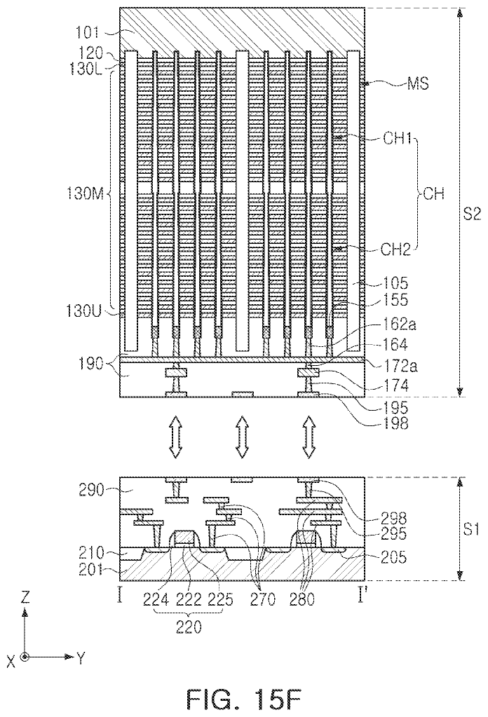

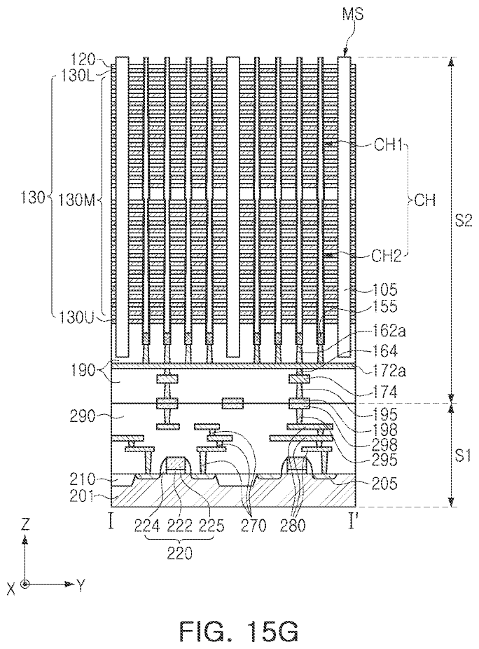

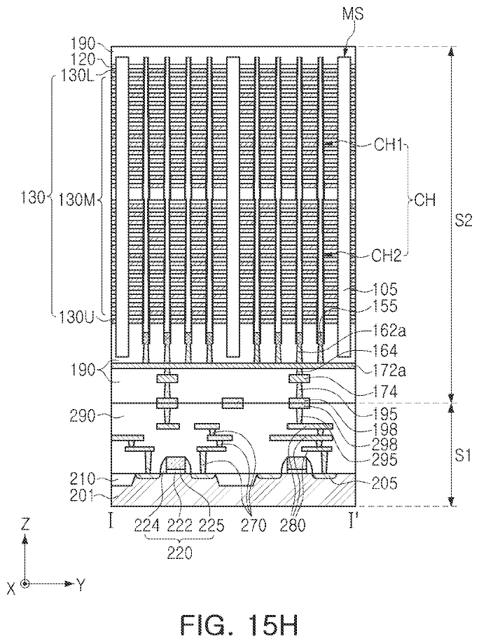

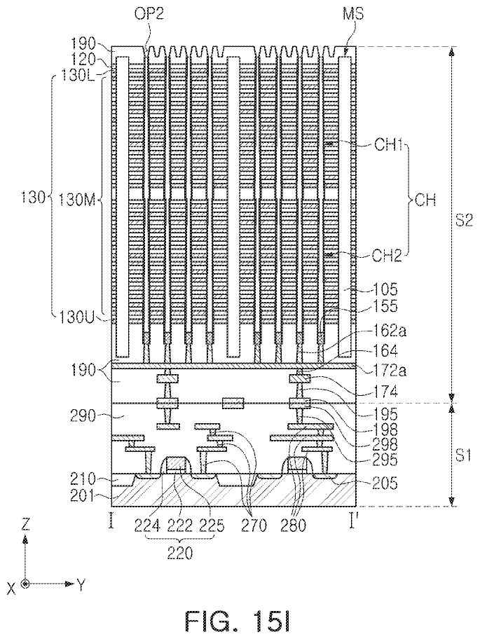

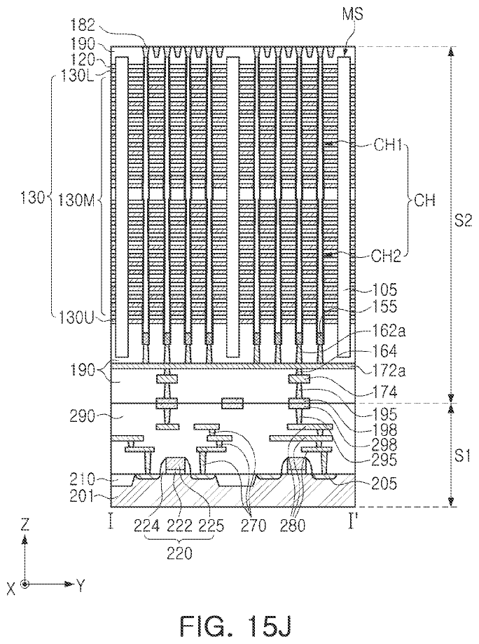

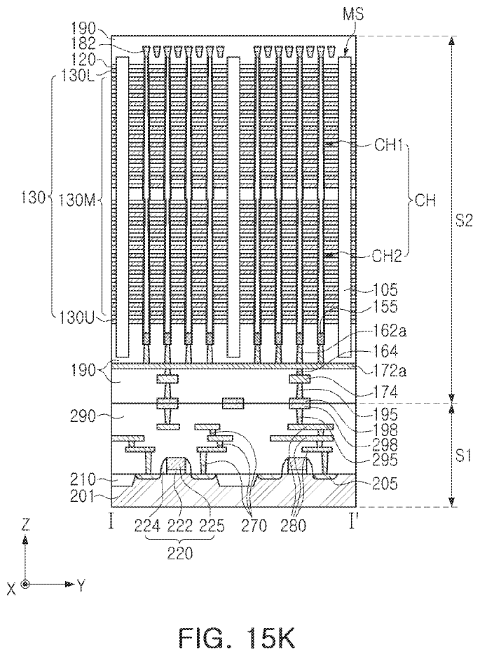

FIGS. 15A to 15K are schematic cross-sectional views illustrating a method of manufacturing a semiconductor device according to exemplary embodiments. FIGS. 15A to 15K illustrate a region corresponding to FIG. 3.

Referring to FIG. 15A, a first semiconductor structure S1 including circuit devices 220, first wiring structures, and a first bonding structure may be formed on the first substrate 201.

First, the device isolation layers 210 may be formed in the substrate 201, and the circuit gate dielectric layer 222 and the circuit gate electrode 225 may be sequentially formed on the substrate 201. The device isolation layers 210 may be formed by, for example, a shallow trench isolation (STI) process. The circuit gate dielectric layer 222 and the circuit gate electrode 225 may be formed using atomic layer deposition (ALD) or chemical vapor deposition (CVD). The circuit gate dielectric layer 222 may be formed of silicon oxide, and the circuit gate electrode 225 may be formed of at least one of polycrystalline silicon or a metal silicide layer, but the present disclosure is not limited thereto. Next, a spacer layer 224 and source/drain regions 205 may be formed on both sidewalls of the circuit gate dielectric layer 222 and the circuit gate electrode 225. In some exemplary embodiments, the spacer layer 224 may be formed of a plurality of layers. The source/drain regions 205 may be formed by performing an ion implantation process.

The circuit contact plugs 270 of the first wiring structure and the first bonding vias 295 of the first bonding structure may be formed by partially forming the peripheral region insulating layer 290, and then removing a portion of the peripheral region insulating layer 290 by performing etching and filling the removed portion with a conductive material. The circuit wiring lines 280 of the first wiring structure and the first metal bonding layers 298 of the first bonding structure may be formed, for example, by depositing a conductive material, and then patterning the conductive material. The first metal bonding layers 298 may be formed to expose upper surfaces thereof through the peripheral region insulating layer 290. The upper surfaces of the first metal bonding layers 298 may form a portion of an upper surface of the first semiconductor structure S1.

The peripheral region insulating layer 290 may include a plurality of insulating layers. A portion of the peripheral region insulating layer 290 may be formed in respective operations of forming the first wiring structure and the first bonding structure. Through this operation, the first semiconductor structure S1 may be prepared.

Referring to FIG. 15B, a manufacturing process of the second semiconductor structure S2 may be started. First, sacrificial insulating layers 118 and interlayer insulating layers 120 may be alternately stacked on the second substrate 101 to form channel sacrificial layers 129, and then the sacrificial insulating layers 118 and the interlayer insulating layers 120 may be alternately stacked again.

The second substrate 101, a layer that is removed through a subsequent process, may be a semiconductor substrate such as a silicon (Si) wafer.

The sacrificial insulating layers 118 may be alternately formed with the interlayer insulating layers 120 to form a lower stack structure and an upper stack structure. After the lower stack structure is formed, the channel sacrificial layers 129 may be formed, and the upper stack structure may be formed.

The sacrificial insulating layers 118 may be layers replaced by the gate electrodes 130 (see FIG. 3) through a subsequent process. The sacrificial insulating layers 118 may be formed of an etchable material capable of being etched with etch selectivity with respect to the interlayer insulating layers 120. For example, the interlayer insulating layer 120 may be formed of at least one of silicon oxide and silicon nitride, and the sacrificial insulating layers 118 may be formed of a material that is different from the selected material of the interlayer insulating layer 120 among silicon, silicon oxide, silicon carbide, and silicon nitride. In exemplary embodiments, the thicknesses of the interlayer insulating layers 120 may not be all the same.

The channel sacrificial layers 129 may be formed by forming lower channel holes to pass through the lower stack structure in a region corresponding to the first channel structures CH1 (see FIG. 3), and then depositing a material for the channel sacrificial layers 129 in the lower channel holes. The lower channel holes may be formed to partially recess the second substrate 101 from an upper surface thereof, but the present disclosure is not limited thereto. The channel sacrificial layers 129 may include, for example, polycrystalline silicon. In this operation, a portion of the cell region insulating layer 190 covering a stack structure of the sacrificial insulating layers 118 may be formed.

Referring to FIG. 15C, channel structures CH passing through a stack structure of the sacrificial insulating layers 118 and the interlayer insulating layers 120 may be formed.

In order to form the channel structures CH, the upper stack structure may be anisotropically etched on the channel sacrificial layers 129 to form upper channel holes and remove the channel sacrificial layers 129 exposed through the upper channel holes. Accordingly, channel holes to which the lower channel holes and the upper channel holes are connected may be formed.

The channel dielectric layer 145, the channel layer 140, the channel filling insulating layer 150, and the channel pad 155 may be sequentially formed in each of the channel holes to form the first and second channel structures CH1 and CH2. The channel layer 140 may be formed on the channel dielectric layer 145 in the channel structures CH. The channel filling insulating layer 150 may be formed to fill the channel structures CH, and may be formed of an insulating material. However, in some exemplary embodiments, a space between the channel layers 140 may be filled with a conductive material instead of the channel filling insulating layer 150. The channel pads 155 may be formed of a conductive material, for example, doped polycrystalline silicon.

Referring to FIG. 15D, first openings OP1 passing through the stack structure of the sacrificial insulating layers 118 and the interlayer insulating layers 120 may be formed, and tunnels TL may be formed by removing the sacrificial insulating layer 118 through the first openings OP1.

The first openings OP1 may be formed in a region corresponding to the isolation regions MS (see FIG. 3), and may be formed in the form of a trench extending in an X-direction. The first openings OP1 may be formed to partially recess the second substrate 101 from an upper surface thereof, but are not limited thereto.

The sacrificial insulating layers 118 may be selectively removed with respect to the interlayer insulating layers 120 using, for example, wet etching. Accordingly, tunnel portions TL may be formed between the interlayer insulating layers 120.

Referring to FIG. 15E, the gate electrodes 130 may be formed and the isolation regions MS may be formed in a region from which the sacrificial insulating layers 118 are removed, and then second wiring structures and a second bonding structure may be formed.

The gate electrodes 130 may be formed by filling the tunnel portions TL with a conductive material. The gate electrodes 130 may include metal, polycrystalline silicon, or a metal silicide material.

In some exemplary embodiments, a dielectric layer may be formed before the gate electrodes 130 are formed. In this case, the dielectric layer may be seen as forming a blocking structure together with a blocking layer of the channel dielectric layer 145 extending vertically along the channel structure CH. The dielectric layer may be formed to extend horizontally along the tunnel portions TL, and may be formed to cover sidewalls of the channel structures CH exposed through the tunnel portions TL.

The isolation regions MS may be formed by depositing the isolation insulating layer 105 by filling the first openings OP1 with an insulating material.

In the second wiring structure, the cell contact plugs 160 may be formed by etching the cell region insulating layer 190 on the channel pads 155 and depositing a conductive material. The cell wiring lines 170 may be formed through a process of depositing and patterning a conductive material, or may be formed by partially forming an insulating layer forming the cell region insulating layer 190, patterning the insulating layer, and depositing a conductive material.

The second bonding vias 195 and the second metal bonding layers 198 forming the second bonding structure may be formed by further forming the cell region insulating layer 190, and then partially removing the cell region insulating layer 190 and depositing a conductive material. Upper surfaces of the second metal bonding layers 198 may be exposed from the cell region insulating layer 190. Upper surfaces of the second metal bonding layers 198 may form a portion of an upper surface of the second semiconductor structure S2.

Referring to FIG. 15F, the first semiconductor structure S1 and the second semiconductor structure S2 may be bonded to each other.

The first semiconductor structure S1 and the second semiconductor structure S2 may be connected to each other by bonding the first metal bonding layers 298 and the second metal bonding layers 198 to each other by pressure. At the same time, bonding insulating layers that are portions of the peripheral region insulating layer 290 and the cell region insulating layer 190 may also be bonded to each other by pressure. The second semiconductor structure S2 may be turned over on the first semiconductor structure S1 so that the second metal bonding layers 198 face downward, and then bonding may be performed.

The first semiconductor structure S1 and the second semiconductor structure S2 may be directly bonded to each other without using an adhesive such as an adhesive layer. In some exemplary embodiments, before bonding is performed, a surface treatment process such as hydrogen plasma treatment may be further performed on an upper surface of the first semiconductor structure S1 and a lower surface of the second semiconductor structure S2 in order to strengthen the bonding strength.

Referring to FIG. 15G, the second substrate 101 of the second semiconductor structure S2 may be removed from a bonding structure of the first and second semiconductor structures S1 and S2.

A portion of the second substrate 101 may be removed from an upper surface thereof by a polishing process such as a grinding process, and the remaining portion may be removed by an etching process such as wet etching and/or dry etching. Alternatively, the entire second substrate 101 may be removed by an etching process. For example, when the channel dielectric layer 145 and the isolation insulating layer 105 include an oxide, the etching process may be performed by setting a condition so that etching is stopped on the oxide. Thus, only the second substrate 101 may be selectively removed, so that the isolation insulating layers 105 and the channel structures CH may be formed to protrude onto the uppermost interlayer insulating layer 120 in a region from which the second substrate 101 is removed. As upper ends of the channel structures CH protrude onto the uppermost interlayer insulating layer 120, upper regions of the channel dielectric layers 145 that are outermost layers of the channel structures CH may be exposed upwards. The exposed channel dielectric layers 145 may be removed to expose upper surfaces of the channel layers 140. The channel dielectric layers 145 may be selectively removed by a wet etching process and/or a dry etching process. Impurities may be implanted into the channel layers 140 by an ion implantation process. A region into which the impurities are implanted may form a contact doped region 140P (see FIG. 7).

Referring to FIG. 15H, the cell region insulating layer 190 may be formed by depositing an insulating material on the second semiconductor structure S2. The cell region insulating layer 190 may be disposed to cover the channel structures CH, the gate electrodes 130, and the isolation regions MS.

Referring to FIG. 15I, second openings OP2 passing through the cell region insulating layer 190 may be formed.

The second openings OP2 may be formed by removing a portion of the cell region insulating layer 190 through an etching process, and a photolithography process may be performed prior to the etching process. When the channel layer 140 includes a conductive material, the etching process may be performed by setting a condition so that etching of the conductive material is stopped. The second openings OP2 may be formed in a region corresponding to the source lines 182 (see FIG. 3), and may be formed in the form of a trench extending in an X-direction. In some exemplary embodiments, the second openings OP2 may be formed to partially recess the channel structures CH from an upper surface thereof, but are not limited thereto.

Referring to FIG. 15J, source lines 182 may be formed.

The source lines 182 may be formed by filling the second openings OP2 (see FIG. 15I) with a conductive material and removing a portion of the conductive material through a polishing process. The source lines 182 may include metal, polycrystalline silicon, or a metal silicide material.

Referring to FIG. 15K, the cell region insulating layer 190 may be formed by depositing an insulating material on the source lines 182. The cell region insulating layer 190 may be disposed to cover the source lines 182. Accordingly, the semiconductor device of FIGS. 1 to 9 may be manufactured.

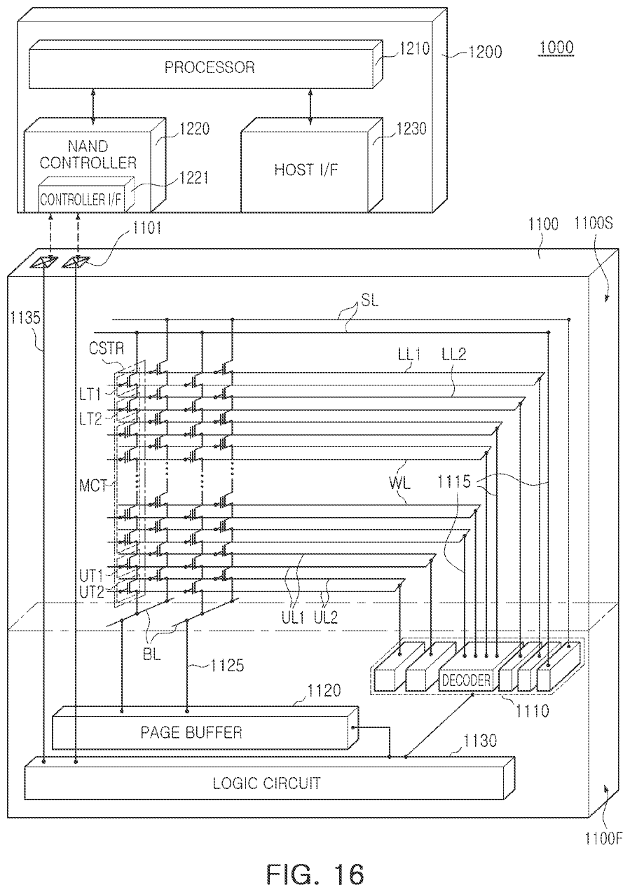

FIG. 16 is a diagram schematically illustrating an electronic system including a semiconductor device according to exemplary embodiments.

Referring to FIG. 16, an electronic system 1000 may include a semiconductor device 1100 and a controller 1200 electrically connected to the semiconductor device 1100. The electronic system 1000 may be a storage device including one semiconductor device 1100 or a plurality of semiconductor devices 1100 or an electronic device including the storage device. For example, the electronic system 1000 may be a solid state drive (SSD) device, a universal serial bus (USB), a computing system, a medical device, or a communication device including one semiconductor device 1100 or the plurality of semiconductor devices 1100.

The semiconductor device 1100 may be a nonvolatile memory device, for example, a NAND flash memory device described above with reference to FIGS. 1 to 14. The semiconductor device 1100 may include a first semiconductor structure 1100F and a second semiconductor structure 1100S on the first semiconductor structure 1100F. In exemplary embodiments, the first semiconductor structure 1100F may be disposed next to the second semiconductor structure 1100S. The first semiconductor structure 1100F may be a peripheral circuit structure including a decoder circuit 1110, a page buffer 1120, and a logic circuit 1130. The second semiconductor structure 1100S may be a memory cell structure including bit lines BL, a source line SL, word lines WL, first and second gate upper lines UL1 and UL2, first and second gate lower lines LL1 and LL2, and memory cell strings CSTR between the bit lines BL and the source line SL.

In the second semiconductor structure 1100S, each of the memory cell strings CSTR may include lower transistors LT1 and LT2 adjacent to the source line SL, upper transistors UT1 and UT2 adjacent to the bit lines BL, and a plurality of memory cell transistors MCT disposed between the lower transistors LT1 and LT2 and the upper transistors UT1 and UT2. In some exemplary embodiments, the number of lower transistors LT1 and LT2 and the number of upper transistors UT1 and UT2 may be changed in various manners.

In exemplary embodiments, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In exemplary embodiments, the lower transistors LT1 and LT2 may include a lower erase control transistor LT1 and a ground selection transistor LT2 connected in series. The upper transistors UT1 and UT2 may include a string selection transistor UT1 and an upper erase control transistor UT2 connected in series. At least one of the lower erase control transistor LT1 and the upper erase control transistor UT2 may be used for an erase operation of deleting data stored in the memory cell transistors MCT using a GIDL phenomenon.

The source line SL, the first and second gate lower lines LL1 and LL2, the word lines WL, and the first and second gate upper lines UL1 and UL2 may be electrically connected to the decoder circuit 1110 through first connection wirings 1115 extending from an interior of the first semiconductor structure 1100F to the second semiconductor structure 1100S. The bit lines BL may be electrically connected to the page buffer 1120 through second connection wirings 1125 extending from an interior of the first semiconductor structure 1100F to the second semiconductor structure 1100S.

In the first semiconductor structure 1100F, the decoder circuit 1110 and the page buffer 1120 may perform a control operation on at least one selection memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wiring 1135 extending from an interior of the first semiconductor structure 1100F to the second semiconductor structure 1100S.

The controller 1200 may include a processor 1210, a NAND controller 1220, and a host interface 1230. In some exemplary embodiments, the electronic system 1000 may include a plurality of semiconductor devices 1100. In this case, the controller 1200 may control the plurality of semiconductor devices 1100.

The processor 1210 may control the overall operation of the electronic system 1000 including the controller 1200. The processor 1210 may operate according to predetermined firmware, and may access the semiconductor device 1100 by controlling the NAND controller 1220. The NAND controller 1220 may include a controller interface 1221 processing communication with the semiconductor device 1100. A control instruction for controlling the semiconductor device 1100, data to be recorded on the memory cell transistors MCT of the semiconductor device 1100, and data to be read from the memory cell transistors MCT may be transmitted through the controller interface 1221. The host interface 1230 may provide a communication function between the electronic system 1000 and an external host. When a control command is received from the external host through the host interface 1230, the processor 1210 may control the semiconductor device 1100 in response to the control command.

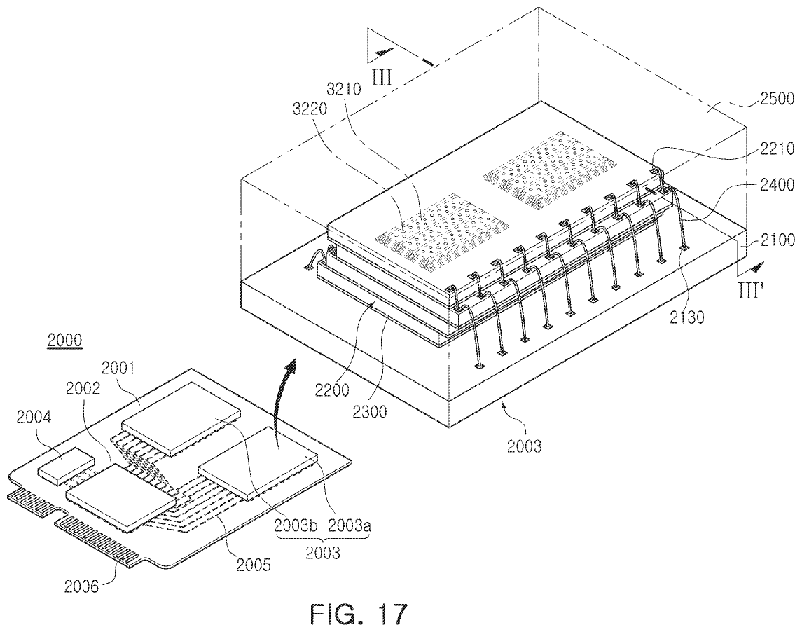

FIG. 17 is a schematic perspective view illustrating an electronic system including a semiconductor device according to an exemplary embodiment.

Referring to FIG. 17, an electronic system 2000 according to an exemplary embodiment may include a main substrate 2001, a controller 2002 mounted on the main substrate 2001, one or more semiconductor packages 2003, and DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins coupled to the external host. The number and arrangement of the plurality of pins in the connector 2006 may vary depending on a communication interface between the electronic system 2000 and the external host. In exemplary embodiments, the electronic system 2000 may communicate with the external host according to any one interface such as a universal serial bus (USB), a peripheral component interconnect express (PCI-Express), a serial advanced technology attachment (SATA), an M-Phy for universal flash storage (UFS), and the like. In exemplary embodiments, the electronic system 2000 may operate by power supplied from the external host through the connector 2006. The electronic system 2000 may further include a power management integrated circuit (PMIC) distributing power supplied from the external host to the controller 2002 and the semiconductor package 2003.

The controller 2002 may record data on or read data from the semiconductor package 2003, and may improve the operating speed of the electronic system 2000.

The DRAM 2004 may be a buffer memory for reducing a speed difference between the semiconductor package 2003 that is a data storage space and the external host. The DRAM 2004 included in the electronic system 2000 may operate as a type of cache memory, and may provide a space for temporarily storing data in a control operation for the semiconductor package 2003. When the DRAM 2004 is included in the electronic system 2000, the controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 respectively disposed on lower surfaces of the semiconductor chips 2200, a connection structure 2400 electrically connecting the semiconductor chips 2200 and the package substrate 2100 to each other, and a molding layer 2500 covering the semiconductor chips 2200 and the connection structure 2400 on the package substrate 2100.

The package substrate 2100 may be a printed circuit board including package upper pads 2130. Each semiconductor chip 2200 may include an input/output pad 2210. The input/output pad 2210 may correspond to the input/output pad 1101 in FIG. 16. Each of the semiconductor chips 2200 may include gate stack structures 3210 and channel structures 3220. Each of the semiconductor chips 2200 may include the semiconductor device described above with reference to FIGS. 1 to 14.

In some exemplary embodiments, the connection structure 2400 may be a bonding wire electrically connecting the input/output pad 2210 and the package upper pads 2130 to each other. Accordingly, in each of the first and second semiconductor packages 2003a and 2003b, the semiconductor chips 2200 may be electrically connected to each other in a bonding wire manner, and may be electrically connected to the package upper pads 2130 of the package substrate 2100. In some exemplary embodiments, in each of the first and second semiconductor packages 2003a and 2003b, the semiconductor chips 2200 may be electrically connected to each other by a connection structure including a through-electrode (through-silicon via, TSV) instead of the connection structure 2400 in the bonding wire manner.

In further exemplary embodiments, the controller 2002 and the semiconductor chips 2200 may be included in one package. In an exemplary embodiment, the controller 2002 and the semiconductor chips 2200 may be mounted on an interposer substrate different from the main substrate 2001, and the controller 2002 and the semiconductor chips may be connected to each other by a wiring formed on the interposer substrate. 2200.

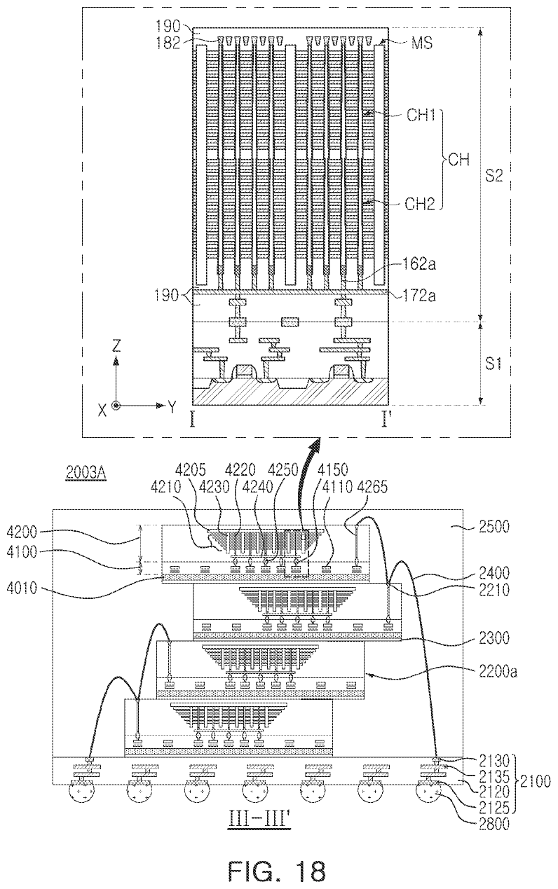

FIG. 18 is a schematic cross-sectional view illustrating a semiconductor package according to an exemplary embodiment. FIG. 18 illustrates an exemplary embodiment of the semiconductor package 2003 in FIG. 17, and conceptually illustrates a region in which the semiconductor package 2003 is cut along cutting line III-III′ in FIG. 17.

Referring to FIG. 18, in a semiconductor package 2003A, each of the semiconductor chips 2200a may include a semiconductor substrate 4010, a first semiconductor structure 4100 on the semiconductor substrate 4010, and a second semiconductor structure 4200 bonded to the first semiconductor structure 4100 on the first semiconductor structure 4100 in a wafer bonding manner.

The first semiconductor structure 4100 may include a peripheral circuit region including a peripheral wiring 4110 and a lower bonding structure 4150. The second semiconductor structure 4200 may include a source line 4205, a gate stack structure 4210 between the source line 4205 and the first semiconductor structure 4100, channel structures 4220 and isolation structures 4230 passing through the gate stack structure 4210, and an upper bonding structure 4250 electrically connected to the channel structures 4220 and word lines of the gate stack structure 4210, respectively. For example, the upper bonding structure 4250 may be electrically connected to the channel structures 4220 and the word lines, respectively, through bit lines 4240 electrically connected to the channel structures 4220 and the gate contact plugs 162b electrically connected to the word lines (see FIG. 4). The lower bonding structure 4150 of the first semiconductor structure 4100 and the upper bonding structure 4250 of the second semiconductor structure 4200 may be bonded to each other while being in contact with each other. Bonded portions of the lower bonding structure 4150 and the upper bonding structure 4250 may be formed of, for example, copper (Cu).

As illustrated in the enlarged view, the second semiconductor structure 4200 may further include a plate conductive layer 206, a vertical conductive layer 273, and a liner insulating layer 275. Each of the semiconductor chips 2200a may further include the input/output pad 2210 and an input/output connection wiring 4265 below the input/output pad 2210. The input/output connection wiring 4265 may be electrically connected to some of the second bonding structures 4210.

The semiconductor chips 2200a in FIG. 18 may be electrically connected to each other by connection structures 2400 that are in the form of bonding wires. However, in exemplary embodiments, semiconductor chips in one semiconductor package, such as the semiconductor chips 2200a in FIG. 18, may be electrically connected to each other by a connection structure including a through-electrode TSV.

While exemplary embodiments have been shown and described above, it will be apparent to those skilled in the art that modifications and variations could be made without departing from the spirit and scope of such exemplary embodiments as defined by the appended claims.

What is claimed is:

1. A semiconductor device comprising:
a first semiconductor structure including a first substrate, circuit devices disposed on the first substrate, and first metal bonding layers disposed on the circuit devices; and
a second semiconductor structure including gate electrodes spaced apart from each other and stacked in a first direction, perpendicular to upper surfaces of the first metal bonding layers, channel structures passing through the gate electrodes, extending in the first direction, and respectively including a channel layer, second metal bonding layers disposed below the channel structures and the gate electrodes and connected to the first metal bonding layers, bit lines disposed below the channel structures, extending in a second direction, perpendicular to the first direction, and spaced apart from each other, and source lines disposed on the channel structures, extending in a third direction, perpendicular to the second direction, and spaced apart from each other,
wherein the channel structures are respectively disposed in intersection regions in which the bit lines and the source lines intersect each other.

2. The semiconductor device of claim 1, wherein the bit lines are respectively disposed below columns in the second direction of the channel structures.

3. The semiconductor device of claim 1, wherein the bit lines extend through central axes in the second direction of the channel structures.

4. The semiconductor device of claim 1, wherein the second semiconductor structure further includes channel contact plugs connecting the bit lines and the channel structures to each other.

5. The semiconductor device of claim 1, wherein the second semiconductor structure further includes source contact plugs connecting the source lines and the circuit devices to each other.

6. The semiconductor device of claim 1, wherein
source lines have an upper width greater than a lower width,
lower portions of the source lines recessing upper portions of the channel structures.

7. The semiconductor device of claim 1, wherein the source lines have a lower width greater than an upper width.

8. The semiconductor device of claim 1, wherein the source lines include a metal material.

9. The semiconductor device of claim 1, wherein the second semiconductor structure further includes a via contact plug connecting each of the source lines and the channel layer to each other.

10. The semiconductor device of claim 1, wherein
channel structures arranged in a line with respect to the third direction among the channel structures form row groups, respectively, and
each of the source lines is connected to one row group among the row groups.

11. The semiconductor device of claim 1, wherein
channel structures arranged in a line with respect to the third direction among the channel structures form row groups, respectively, and
each of the source lines is connected to a plurality of row groups among the row groups.

12. The semiconductor device of claim 1, wherein
each of the channel structures further includes a gate dielectric layer disposed between the gate electrodes and the channel layer, and
an upper end of the gate dielectric layer is positioned at a level that is substantially the same as that of an upper end of the channel layer.

13. The semiconductor device of claim 1, wherein
the channel layer includes a contact doped region, and
the contact doped region is in contact with each of the source lines.

14. The semiconductor device of claim 1, wherein
the second semiconductor structure further includes isolation regions passing through all of the gate electrodes and extending in the second direction,
a unit region of each of the gate electrodes is defined between a pair of adjacent isolation regions among the isolation regions, and
the source lines include block shared source lines overlapping the isolation regions and extending in the second direction.

15. The semiconductor device of claim 1, wherein
the second semiconductor structure further includes isolation regions passing through all of the gate electrodes and extending in the second direction,
a unit region of each of the gate electrodes is defined between a pair of adjacent isolation regions among the isolation regions,
the gate electrodes include memory gate electrodes forming memory cells and at least one upper gate electrode positioned below the memory gate electrodes, and
the upper gate electrode is in an equipotential state in the unit region.

16. A semiconductor device comprising:
a first substrate;
circuit devices disposed on the first substrate;
first metal bonding layers disposed on the circuit devices;
gate electrodes spaced apart from each other and stacked in a first direction, perpendicular to upper surfaces of the first metal bonding layers;
channel structures passing through the gate electrodes, extending in the first direction, and respectively including a channel layer;
second metal bonding layers disposed below the channel structures and the gate electrodes and connected to the first metal bonding layers;
bit lines electrically connected to the channel structures, extending in a second direction, perpendicular to the first direction, and spaced apart from each other; and
source lines electrically connected to the channel structures, extending in a third direction, perpendicular to the second direction, and spaced apart from each other,
wherein a plurality of first selection channel structures are selected from among the channel structures by an electrical signal applied to the channel layer through the bit lines, and a second selection channel structure is selected from among the plurality of first selection channel structures by an electrical signal applied to the channel layer through the source lines.

17. The semiconductor device of claim 16, wherein
the channel structures include first and second row groups respectively arranged in a line in the third direction and arranged adjacent to each other in the second direction, and
the source lines include first and second source lines for applying an electrical signal to each of the first and second row groups.

18. The semiconductor device of claim 16, wherein
the channel structures include first and second column groups respectively arranged in a line in the second direction and arranged adjacent to each other in the third direction, and
the bit lines include first and second bit lines for applying an electrical signal to each of the first and second column groups.

19. An electronic system comprising:
a semiconductor device including a first substrate, circuit devices disposed on the first substrate, first metal bonding layers disposed on the circuit devices, gate electrodes spaced apart from each other and stacked in a first direction, perpendicular to upper surfaces of the first metal bonding layers, channel structures passing through the gate electrodes, extending in the first direction, and respectively including a channel layer, second metal bonding layers disposed below the channel structures and the gate electrodes and connected to the first metal bonding layers, bit lines extending in a second direction, perpendicular to the first direction and spaced apart from each other, source lines extending in a third direction, perpendicular to the second direction and spaced apart from each other, and input/output pads electrically connected to the circuit devices, wherein a plurality of first selection channel structures are selected from among the channel structures by an electrical signal applied to the channel layer through the bit lines, and a second selection channel structure is selected from among the plurality of first selection channel structures by an electrical signal applied to the channel layer through the source lines; and
a controller electrically connected to the semiconductor device through the input/output pad and controlling the semiconductor device.

20. The electronic system of claim 19, wherein the semiconductor device further includes a channel contact plug connected to each of the bit lines, and a source contact plug connected to each of the source lines.
